(19) United States
(12) Patent Application Publication
(10) Pub. No.: US 2026/0353590 A1
(43) Pub. Date: Nov. 5, 2026

(54) Server System Cable Management System

(71) Applicant: Dell Products L.P., Round Rock, TX (US)

(72) Inventors: Chih-Ta Huang, Taipei (TW); Ching-Yuan Wang, New Taipei City (TW); Tingchun Kuo, Taipei City (TW); Gabriel Braun, Pflugerville, TX (US)

(21) Appl. No.: 19/198,410

(22) Filed: May 5, 2025

(51) Int. Cl. H05K 7/14

(52) U.S. Cl. CPC H05K 7/1491

(57) ABSTRACT

A cable management system for use with an information handling system. The cable management system includes a cable; and, a cable management component, the cable management component. The cable management component includes a housing, the housing being configured to mount to a side of a chassis of the information handling system; and, a cable routing portion physically coupled to the mounting bracket portion, the cable routing portion being configured to route the cable while preventing air flow backflow.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a server system with a cable management system.

In one embodiment, the invention relates to a cable management component of a cable management system for an information handling system, comprising: a housing, the housing being configured to mount to a side of a chassis of the information handling system; and; a cable routing portion physically coupled to the mounting bracket portion, the cable routing portion being configured to route a cable while preventing air flow backflow.

In another embodiment, the invention relates to cable management system for use in an information handling system comprising: a cable; and, a cable management component, the cable management component comprising: a housing, the housing being configured to mount to a side of a chassis of the information handling system; and; a cable routing portion physically coupled to the mounting bracket portion, the cable routing portion being configured to route a cable while preventing air flow backflow.

In another embodiment, the invention relates to a system comprising: a chassis; a cable contained within the chassis; a component contained within the chassis; and, a cable management component, the cable management component comprising: a housing, the housing being configured to mount to a side of the chassis of the information handling system; and; a cable routing portion physically coupled to the mounting bracket portion, the cable routing portion being configured to route a cable while preventing air flow backflow.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example server type information handling system.

FIGS. 4A and 4B, generally referred to as FIG. 4, show views of a cable management system.

FIGS. 5A and 5B, generally referred to as FIG. 5, show views of a cable management system with cables installed.

### DETAILED DESCRIPTION

Various aspects of the present disclosure include an appreciation that it is known to route one or more cables within information handling systems such as server type information handling systems. Various aspects of the present disclosure include an appreciation that certain known information handling systems include cables that are routed between a front portion of the information handling system and a rear of the information handling system. Various aspects of the present disclosure include an appreciation that with certain known information handling systems cables are routed between a front portion of the information handling system and a rear of the information handling system via channels located along the sides of interior of the chassis of the information handling system. Various aspects of the present disclosure include an appreciation that the cables can include peripheral component interconnect express (PCIe) type cables.

Various aspects of the present disclosure include an appreciation that with certain information handling system chassis, routing of the cables can be challenging due to, for example, a reduced internal width of certain areas within the chassis.

Various aspects of the present disclosure include an appreciation that some known server type information handling systems include a U-shaped cable holder via which cables are routed between a front portion of the information handling system and a rear of the information handling system. Various aspects of the present disclosure include an appreciation that the U-shaped cable holder often includes a pair of vertical elastomeric components which deform when one or more cables are routed via the cable holder. Various aspects of the present disclosure include an appreciation that when the vertical elastomeric components deform, one or more voids are formed between the vertical elastomeric components. Various aspects of the present disclosure include an appreciation that the voids can allow air flow backflow within the information handling system, thus resulting in reduced cooling efficiency within the information handling system.

Accordingly, various aspects of the present disclosure include an appreciation that it would be desirable to manage cables within a chassis of an information handling system while reducing any airflow backflow within the information handling system. Additionally, various aspects of the present disclosure include an appreciation that so managing the cables would facilitate the installation of the cables within the information handling system.

A system and method are disclosed for providing an information handling system with a cable management system. In certain embodiments, the cable management system is integrated into the chassis, facilitating assembly and service. In certain embodiments, cable management system includes a cable and cable routing component.

In certain embodiments, the cable routing component includes a housing, a cable routing portion, or a combination thereof. In certain embodiments, the cable routing portion is configured to route one or more cables while preventing air flow backflow. In certain embodiments, the cable routing portion includes a plurality of elastomeric components. In certain embodiments, the plurality of elastomeric components are mounted vertically within the housing. In certain embodiments, pairs of the plurality of elastomeric components are mounted vertically within the housing.

Such a cable management system advantageously facilitates assembly and service of an information handling system such as a server type information handling system. Such a cable management system advantageously prevents air flow backflow across the cable management system.

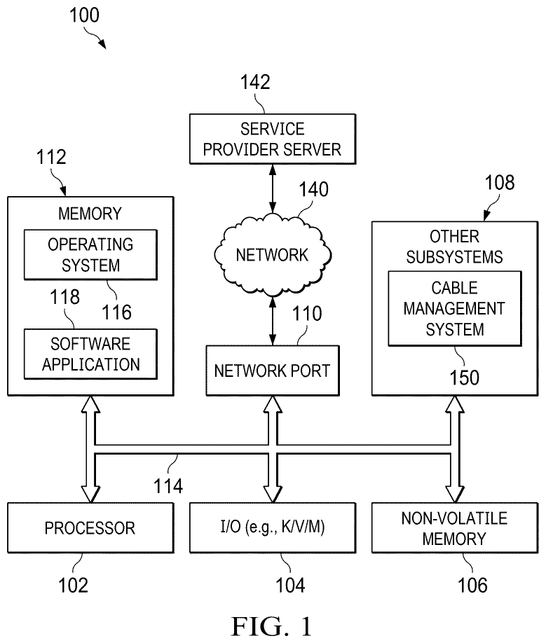

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. In various embodiments, one or both the other subsystems 108 or the network port 110 include a cable management system 150. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power supplies for supplying power to the other components of the information handling system 100.

In certain embodiments, the information handling system 100 comprises a server type information handling system. In certain embodiments, the server type information handling system comprises a blade server type information handling system. As used herein, a blade server type information handling system broadly refers to an information handling system which is physically configured to be mounted within a server rack.

In certain embodiments, the cable management system 150 is integrated into the chassis, facilitating assembly and service. In certain embodiments, cable management system 150 includes a cable and cable routing component.

In certain embodiments, the cable routing component includes a housing, a cable routing portion, or a combination thereof. In certain embodiments, the cable routing portion is configured to route one or more cables while preventing air flow backflow. In certain embodiments, the cable routing portion includes a plurality of elastomeric components. In certain embodiments, the plurality of elastomeric components are mounted vertically within the housing. In certain embodiments, pairs of the plurality of elastomeric components are mounted vertically within the housing.

Such a cable management system 150 advantageously facilitates assembly and service of an information handling system such as a server type information handling system. Such a cable management system advantageously prevents air flow backflow across the cable management system.

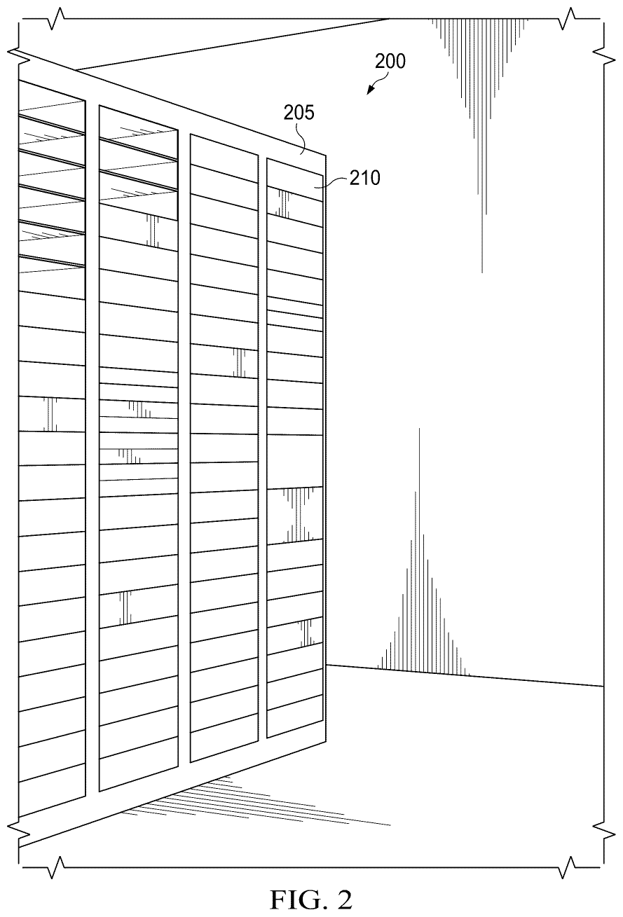

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100, as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit, and a 4U rack unit. In general, a 1U rack unit is substantially (i.e., +/−20%) 1.75″ high, a 2U rack unit is substantially (i.e., +/−20%) 3.5″ high, and a 4U rack height is substantially (i.e., +/−20%) 7.0″ high.

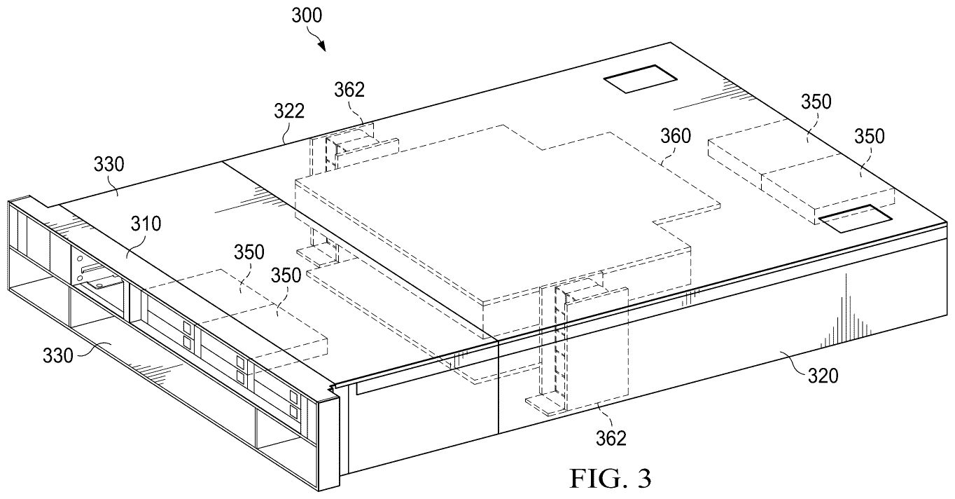

FIG. 3 shows a generalized perspective view of an example blade server type information handling system 300. In certain embodiments, the server type information handling system includes a front portion 310, which is accessible when the server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the server type information handling system can slide out from the rack via the respective mechanical guiding features. In certain embodiments, internal components of the blade type information handling system 300 may be accessed by removing a top panel 330 of the blade type information handing system 300.

In certain embodiments, the blade type information handing system 300 includes a one or more device bays 350. In certain embodiments, the information handling system 300 includes a high performance module (HPM) 360 (also referred to as a motherboard or a planar board) as well as one or more cable management systems 362. In certain embodiments, each cable management system 362 corresponds to the cable management system 150. In certain embodiments, the information handling system 300 includes cables that are routed between a front of the information handling system and a rear of the information handling system. In certain embodiments, the one or more cable management systems 362 route the cables through channels located along sides of an interior of the chassis between a front of the information handling system and a rear of the information handling system.

In certain embodiments, the cable management system 362 is integrated into the chassis, facilitating assembly and service. In certain embodiments, the cable management system 362 includes at least one cable and cable routing component.

In certain embodiments, the cable routing component includes a housing, a cable routing portion, or a combination thereof. In certain embodiments, the cable routing portion is configured to route one or more cables while preventing air flow backflow. In certain embodiments, the cable routing portion includes a plurality of elastomeric components. In certain embodiments, the plurality of elastomeric components are mounted vertically within the housing. In certain embodiments, pairs of the plurality of elastomeric components are mounted vertically within the housing.

Such a cable management system 362 advantageously facilitates assembly and service of an information handling system such as a server type information handling system. Such a cable management system advantageously prevents air flow backflow across the cable management system.

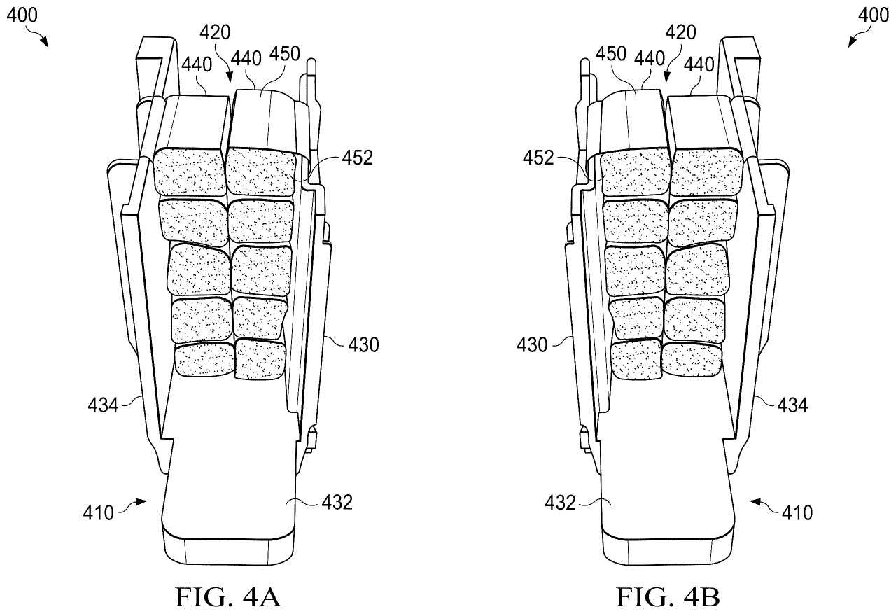

FIGS. 4A and 4B, generally referred to as FIG. 4, show views of a cable management component 400. More specifically, FIG. 4A shows a front perspective view of a cable management component 400. FIG. 4B shows a front perspective view of a cable management component 400. In certain embodiments, cable management component 400 corresponds to the cable management component of the cable management system 150.

In certain embodiments, the cable management component 400 includes a housing 410, a cable routing portion 420, or a combination thereof. In certain embodiments, the cable routing portion 420 is physically coupled to the housing 410. In certain embodiments, the housing 410 is configured to mount to a side of a chassis when the cable management component 400. In certain embodiments, the housing 410 of the cable management component 400 shown in FIG. 4A is configured to mount to a left side of the chassis. In certain embodiments, the housing 410 of the cable management component 400 shown in FIG. 4B is configured to mount to a right side of the chassis. In certain embodiments, the housing 410 of the cable management component 400 shown in FIG. 4A and the housing 410 of the cable management component 400 shown in FIG. 4B are mirror images of each other.

In certain embodiments, the housing 410 includes an exterior wall component 430, a bottom component 432, an interior wall component 434, or a combination thereof. In certain embodiments, the exterior wall component 430 extends substantially, (i.e., +/−20%) perpendicular from the bottom component 432. In certain embodiments, the interior wall component 434 extends substantially, (i.e., +/−20%) perpendicular from the bottom component 432. In certain embodiments, the exterior wall component 430, the bottom component 432, and the interior wall component 434 are constructed from a single piece of material.

In certain embodiments, the housing 410 is constructed from plastic. In certain embodiments, the housing is constructed from a polyester film such as a polyethylene terephthalate (PET) type material. In certain embodiments, the housing 410 surrounds the cable routing portion 420 along a first side edge, a second side edge, a bottom edge, or a combination thereof. The cable routing portion 420 allows routing of a cable along a chassis side wall. In certain embodiments, the cable routing portion 420 is attached to the housing 410 via adhesive. In certain embodiments, a first side edge, a second side edge, a bottom edge, or a combination thereof of the cable routing portion 420 are attached to the mounting bracket portion 410 via adhesive.

In certain embodiments, the cable routing portion 420 is configured to route one or more cables while preventing air flow backflow. In certain embodiments, the cable routing portion 420 includes a plurality of elastomeric components 440. In certain embodiments, each of the plurality of elastomeric components 440 is configured to change its shape independent of any of the other elastomeric components 440. In certain embodiments, the plurality of elastomeric components 440 are arranged in pairs. In certain embodiments, the plurality of elastomeric components 440 are mounted vertically within the housing 410. In certain embodiments, pairs of the plurality of elastomeric components 440 are mounted vertically within the housing 410. In certain embodiments, a first column of the plurality of elastomeric components 440 are mounted vertically to a first interior side wall of the housing 410. In certain embodiments, a second column of the plurality of elastomeric components 440 are mounted vertically to a second interior side wall of the housing 410. In certain embodiments, a first column of the plurality of elastomeric components 440 are mounted vertically to the exterior side wall 430 of the housing 410. In certain embodiments, a second column of the plurality of elastomeric components 440 are mounted vertically to the interior side wall 434 of the housing 410.

In certain embodiments, the x and y dimensions of each of the plurality of elastomeric components 440 are sized to substantially (i.e., +/−25%) correspond to a diameter of cable being routed through the cable routing portion 420. In certain embodiments, each of the plurality of elastomeric components 440 include a sheath component 450, an elastomeric component 452, or a combination thereof. In certain embodiments, the sheath component 450 surrounds the elastomeric component 452 on a first side, a second side, a top side, a bottom side, or a combination thereof. In certain embodiments, the sheath component 450 is constructed from a flexible material which is capable of recovering its shape after pressure is removed. In certain embodiments, the elastomeric component 452 is constructed from a sponge like material which is capable of recovering its shape after pressure is removed.

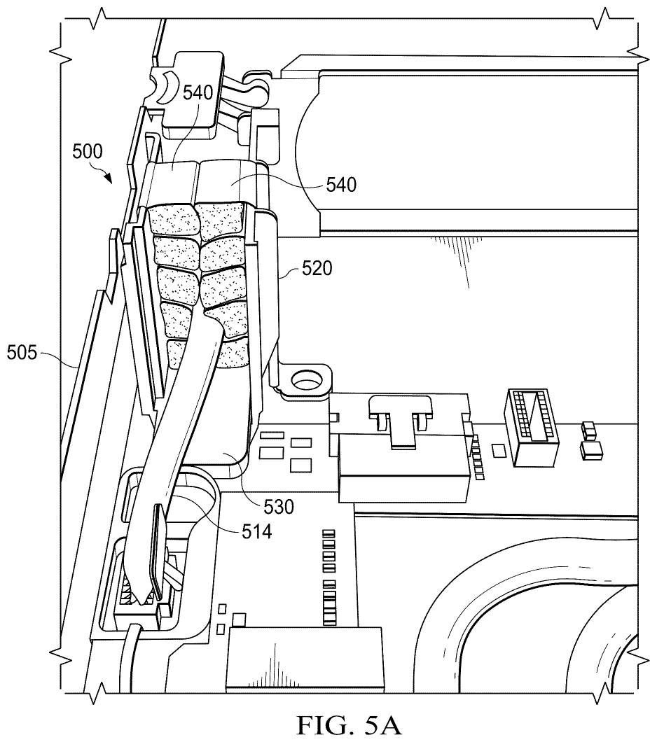

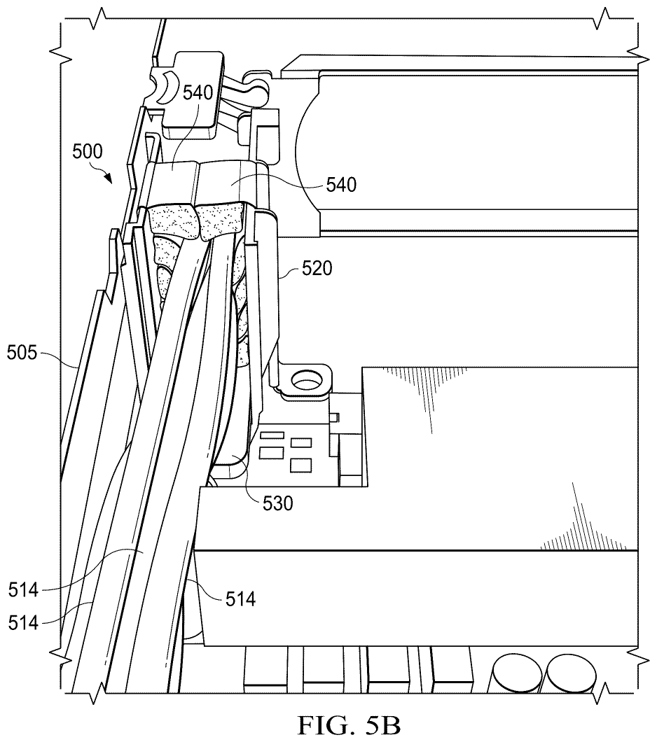

FIGS. 5A and 5B, generally referred to as FIG. 5, show views of a cable management system 500 and a portion of an information handling system chassis 505. More specifically, FIG. 5A shows a rear perspective view of a cable management system 500 with a single routed cable. FIG. 5B shows a rear perspective view of a cable management system 500 with a plurality of routed cables. In certain embodiments, the cable management system 500 corresponds to cable management system 150.

In certain embodiments, the cable management system 500 includes a portion of the chassis 505, one or more cables 514, a cable routing component 520, or a combination thereof. In certain embodiments, the portion of the chassis 505 includes a side wall of the chassis 505. In certain embodiments, the side wall of the chassis and the component of the information handling system, such as a fan system, are laterally spaced apart to provide an area through which one or more cables 514 may be passed.

In certain embodiments, the cable routing component 520 is mounted between the component of the information handling system and the side wall of the information handling system chassis 505, facilitating assembly and service. In certain embodiments, the cable routing component 520 routes the one or more cables 514, neatly managing the one or more cables 514 in the area between the component of the information handling system and the side wall of the information handling system chassis 505. In certain embodiments, the cable routing component 520 routes the one or more cables 514 in the area between the component of the information handling system and the side wall of the information handling system chassis 505 while preventing air flow backflow.

In certain embodiments, the cable routing component 520 includes a housing 530, a plurality of elastomeric components 540, or a combination thereof. In certain embodiments, each of the plurality of elastomeric components 540 is configured to change its shape independent of any of the other elastomeric components 540. In certain embodiments, the plurality of elastomeric components 540 are arranged in pairs. In certain embodiments, the plurality of elastomeric components 540 are mounted vertically within the housing 530. In certain embodiments, pairs of the plurality of elastomeric components 540 are mounted vertically within the housing 530. In certain embodiments, a first column of the plurality of elastomeric components 540 are mounted vertically to a first interior side wall of the housing 530. In certain embodiments, a second column of the plurality of elastomeric components 540 are mounted vertically to a second interior side wall of the housing 530.

In certain embodiments, one or more of the plurality of elastomeric components 540 individually deform when a cable 514 is routed through the cable routing component 520. In certain embodiments, when more cables 514 are routed through the cable routing component more of the plurality of elastomeric components 540 deform. In certain embodiments, by individual elastomeric components 540 deforming based upon how many cables 514 are routed through the cable routing component 520, air flow backflow through the cable routing component is prevented.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A cable management component of a cable management system for an information handling system, comprising:
a housing, the housing being configured to mount to a side of a chassis of the information handling system; and;
a cable routing portion physically coupled to the mounting bracket portion, the cable routing portion being configured to route a cable while preventing air flow backflow.

2. The cable management component of claim 1, wherein:
the cable routing portion includes a plurality of elastomeric components, each of the plurality of elastomeric components being configured to change shape independent of any other elastomeric components.

3. The cable management component of claim 2, wherein:
the plurality of elastomeric components are arranged in pairs.

4. The cable management component of claim 3, wherein:
pairs of the plurality of elastomeric components are mounted vertically within the housing.

5. The cable management component of claim 2, wherein:
a first column of the plurality of elastomeric components are mounted vertically to a first interior side wall of the housing; and,
a second column of the plurality of elastomeric components are mounted vertically to a second interior side wall of the housing.

6. The cable management component of claim 2, wherein:
each of the plurality of elastomeric components includes a sheath component and an elastomeric component, the sheath component surrounding the elastomeric component.

7. A cable management system for use in an information handling system comprising:
a cable; and,
a cable management component, the cable management component comprising:
a housing, the housing being configured to mount to a side of a chassis of the information handling system; and,
a cable routing portion physically coupled to the mounting bracket portion, the cable routing portion being configured to route the cable while preventing air flow backflow.

8. The cable management system of claim 7, wherein:
the cable routing portion includes a plurality of elastomeric components, each of the plurality of elastomeric components being configured to change shape independent of any other elastomeric components.

9. The cable management system of claim 8, wherein:
the plurality of elastomeric components are arranged in pairs.

10. The cable management system of claim 9, wherein:
pairs of the plurality of elastomeric components are mounted vertically within the housing.

11. The cable management system of claim 8, wherein:
a first column of the plurality of elastomeric components are mounted vertically to a first interior side wall of the housing; and,
a second column of the plurality of elastomeric components are mounted vertically to a second interior side wall of the housing.

12. The cable management system of claim 8, wherein:
each of the plurality of elastomeric components includes a sheath component and an elastomeric component, the sheath component surrounding the elastomeric component.

13. A system comprising:
a chassis;
a cable contained within the chassis;
a component contained within the chassis; and, a cable management component mounted between a side wall of the chassis and the component, the cable management component comprising:
a housing, the housing being configured to mount to a side of the chassis of the information handling system; and;
a cable routing portion physically coupled to the mounting bracket portion, the cable routing portion being configured to route the cable while preventing air flow backflow.

14. The system of claim 13, wherein:
the cable routing portion includes a plurality of elastomeric components, each of the plurality of elastomeric components being configured to change shape independent of any other elastomeric components.

15. The system of claim 14, wherein:
the plurality of elastomeric components are arranged in pairs.

16. The system of claim 15, wherein:
pairs of the plurality of elastomeric components are mounted vertically within the housing.

17. The system of claim 14, wherein:
a first column of the plurality of elastomeric components are mounted vertically to a first interior side wall of the housing; and,
a second column of the plurality of elastomeric components are mounted vertically to a second interior side wall of the housing.

18. The system of claim 14, wherein:
each of the plurality of elastomeric components includes a sheath component and an elastomeric component, the sheath component surrounding the elastomeric component.
